(19) United States
(12) Patent Application Publication
(10) Pub. No.: US 2004/0222426 A1
(43) Pub. Date: Nov. 11, 2004

(54) LIGHT EMITTING DIODE MODULE STRUCTURE

(76) Inventor: Bear Hsiung, Taipei (TW)

Correspondence Address: BROWDY AND NEIMARK, P.L.L.C., 624 NINTH STREET, NW, SUITE 300, WASHINGTON, DC, 20001-5303, US

(21) Appl. No.: 10/430,399

(22) Filed: May 7, 2003

(51) Int. Cl. H01L 27/15

(52) U.S. Cl. 257/79

(57) ABSTRACT

An LED module structure has a circuit board, an LED chip, a metal sheet, a housing and a focusing lens. The metal sheet is disposed below the circuit board. The LED chip is received in a groove of the circuit board. The lower side of the LED chip is electrically connected to the upper side of the metal sheet. The upper side of the LED chip is electrically connected to the upper side of the circuit board with a lead. The circuit board and the metal sheet are received in the housing. The circuit board also achieves electric connection with the housing. The focusing lens is disposed above the LED chip. The LED module structure has the advantages of high brightness, better heat-radiating efficiency, convenient assembly and a simplified fabrication process.

### BACKGROUND OF THE INVENTION

1. Field of the Invention

The present invention relates to a light emitting diode module structure and, more particularly, to a light emitting diode module structure having high brightness, better heat-radiating efficiency, convenient assembly and simplified fabrication process.

2. Description of the Related Art

A light emitting diode (LED) is an electronic component made of single crystal semiconductor material. Presently, red and green LEDs of the three primary colors are mass-produced. Because of high reliability, simple control of ON and OFF states of light emission point, and capability of displaying digit and text with segments, LEDs have broad and convenient applications, and have gradually replaced conventional illumination light sources. However, for a conventional LED to meet the requirement of high brightness, a larger current is required, hence easily causing an increase of temperature and a problem of heat radiation.

FIG. 1 shows a conventional LED, wherein a bowl 91 is formed on a circuit board 90 having an anode circuit and a cathode circuit. An LED chip 92 is disposed in the bowl 91. The LED chip 92 is connected to the anode circuit or the cathode circuit with a lead. A gel 94 covers the LED chip 92. The circuit board 90 is a nonconductive base layer 901 with a circuit board 902 for forming the anode circuit and cathode circuit disposed thereon. A conductive layer 903 capable of allowing the connection of pins to the circuit layer 902 is disposed below the base layer 901. For this conventional LED, heat generated by the LED chip 92 cannot be quickly transferred to the conductive layer 903, hence resulting in an inferior heat-radiating efficiency. The LED chip 92 will thus easily burn out. Moreover, both the anode circuit and cathode circuit of the circuit layer 902 are disposed above the circuit board 90, and it is thus necessary for two pins 95 and 96 to pass through the circuit board 90 and protrude therebelow. Assembly is hence inconvenient and the fabrication process complex.

Accordingly, the above conventional LED is inconvenient and has drawbacks in practical fabrication and use. The present invention aims, to solve the problems in the prior art.

### SUMMARY OF THE INVENTION

The primary object of the present invention is to provide an LED module structure, wherein an LED chip is directly disposed on a metal sheet having good electric and heat conductance effects. Heat generated by the LED chip can thus be quickly transferred to the metal sheet for assisting in radiating heat, hence resulting in a better heat-radiating efficiency. Therefore, the LED chip can stably exploit its high brightness characteristic and will not burn out.

Another object of the present invention is to provide an LED module structure, whose wires need not pass through a circuit board, hence providing a more convenient assembly and simplifying the fabrication process.

To achieve the above objects, the present invention provides an LED module structure, which comprises a circuit board, a metal sheet, an LED chip, a housing and a focusing lens. The circuit board has a groove. The metal sheet is disposed below the circuit board. The LED chip is received in the groove. The lower side of the LED chip is electrically connected to the upper side of the metal sheet. The upper side of the LED chip is electrically connected to the upper side of the circuit board with a lead. A gel covers the LED chip. The housing has a receiving space therein. The circuit board and the metal sheet are received in the receiving space. The circuit board also achieves electric connection with the housing. The focusing lens is disposed in the receiving space of the housing, and is located above the LED chip.

### BRIEF DESCRIPTION OF THE DRAWINGS

The various objects and advantages of the present invention will be more readily understood from the following detailed description when read in conjunction with the appended drawing, in which:

FIG. 1 is a cross-sectional view of a conventional LED;

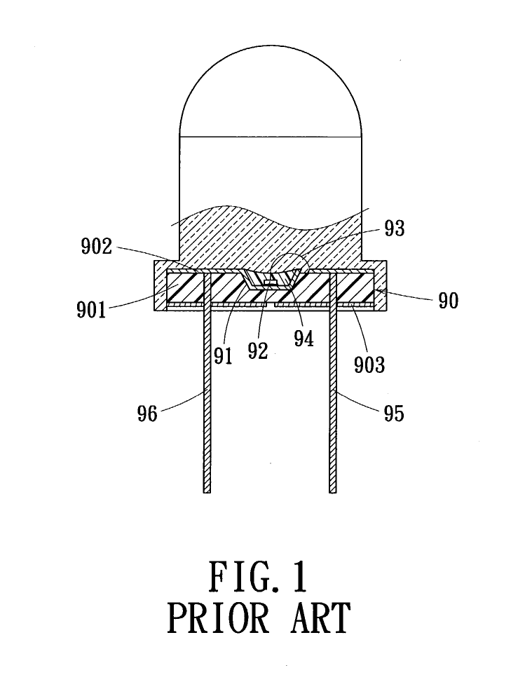

FIG. 2 is an exploded perspective view of the present invention;

FIG. 3 is a perspective assembly view of the present invention; and

FIG. 4 is a cross-sectional view of the present invention.

### DETAILED DESCRIPTION OF THE PREFERRED EMBODIMENT

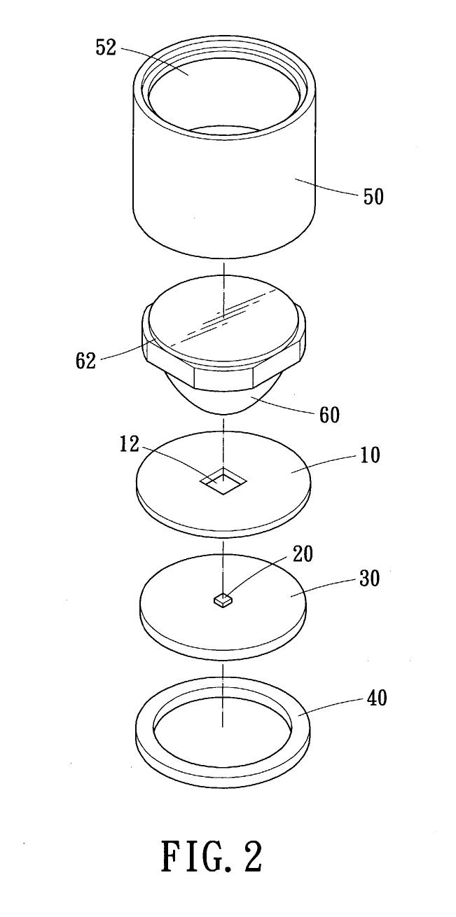

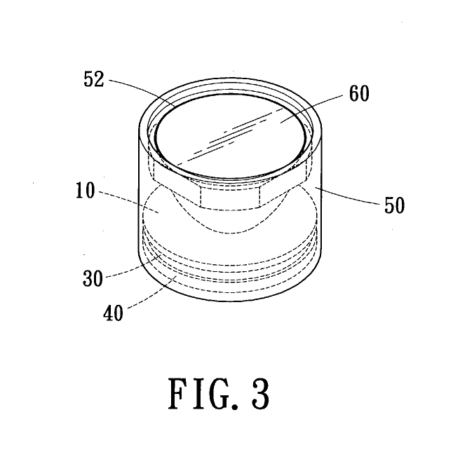

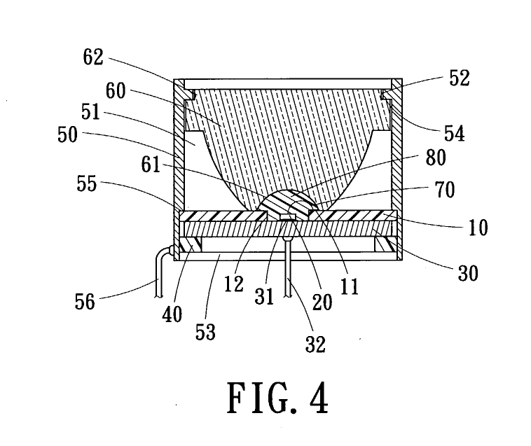

As shown in FIGS. 2, 3 and 4, an LED module structure of the present invention comprises a circuit board 10, an LED chip 20, a metal sheet 30, an insulator 40, a housing 50 and a focusing lens 60. The circuit board (printed circuit board) 10 is of board of circular or other shape. A cathode circuit 11 is provided on the upper side of the circuit board 10. A groove 12 is disposed on the circuit board 10. The groove 12 penetrates through the upper side and lower side of the circuit board 10. The LED chip 20 is a high-brightness chip received in the groove 12.

The metal sheet 30 is made of metal material having good electric and heat conductance effects like copper. The metal sheet 30 is a sheet of circular or other shape. The metal sheet 30 is disposed below the circuit board 10, and has an area smaller than that of the circuit board 10. That is, the outer edge of the metal sheet 30 shrinks more inwards than that of the circuit board 10 to avoid contact between the outer edge of the metal sheet 30 and the inner edge of the housing 50, which would cause a short circuit.

The lower side (anode) of the LED chip 20 is electrically connected to the upper side of the metal sheet 30 with a conductive gel (e.g., silver gel) 31 to allow electrical connection between the LED chip 20 and the metal sheet 30. The upper side (cathode) of the LED chip 20 is electrically connected to the cathode circuit 11 on the upper side of the circuit board 10 with a lead 70 to allow electrical connection between the LED chip 20 and the circuit board 10. A gel 80 covers the LED chip 20 to protect and fix the LED chip 20.

The insulator 40 is made of insulating material like ceramic, and is a ring or other shape. The insulator 40 can also be made by adding an insulating sheet (not shown) onto a metal ring. The insulator 40 is disposed below the metal sheet 30.

The housing 50 is made of metal material having good electric and heat conductance effects like copper. The housing 50 is a hollow body of circular or other shape, and has a receiving space 51 therein. The upper and lower ends of the receiving space 51 form a first opening 52 and a second opening 53, respectively. The internal diameter of the first opening 52 is smaller than that of the receiving space 51 to allow the upper edge of the receiving space 51 to form a ring-shaped first stop edge 54. The internal diameter of the second opening 53 is larger than that of the receiving space 51 to allow the lower edge of the receiving space 51 to form a ring-shaped second stop edge 55.

The circuit board 10, the metal sheet 30 and the insulator 40 are received in the second opening 53 of the housing 50. The circuit board 10 can abut the second stop edge 55 for positioning. The insulator 40 and the housing 50 can be riveted together to firmly position the circuit board. 10, the metal sheet 30 and the insulator 40. The outer edge of the cathode circuit 11 of the circuit board 10 contacts the housing 50 to achieve electric connection. The upper side of the LED chip 20, the lead 70, the circuit board 10 and the housing 50 can thus achieve electric connection so that electricity can be input to the LED chip 20.

The focusing lens 60 is made of transparent material like acrylic. The focusing lens 60 is disposed in the receiving space 51 of the housing 50. The focusing lens 60 is located above the LED chip 20. A cavity 61 corresponding to the gel 80 and the LED chip 20 is disposed the lower end of the focusing lens 60. The upper end of the focusing lens 60 abuts the first stop edge 54 for positioning. A flange 62 is disposed at the upper end of the focusing lens 60. The flange 62 abuts the inner edge of the first opening 52 of the housing 50 so that the focusing lens 60 can be firmly positioned in the receiving space 51 of the housing 50. An LED module structure of the present invention is thus formed.

When the present invention is in practical use, anode electricity can be input to the metal sheet 30 and the lower side of the LED chip 20 with a connection wire 32, and cathode electricity can be input to the housing 50, the circuit board 10, the lead 70 and the upper side of the LED chip 20 with a connection wire 56, thereby driving the LED chip 20 to emit light. The light can be focused by the focusing lens 60 and then be projected out. An LED module structure of high brightness can thus be formed to display digits and texts or be used as an illumination light source.

In the present invention, the LED chip 20 is directly disposed on the metal sheet 30 having good electric and heat conductance effects. Heat generated by the LED chip 20 can thus be quickly transferred to the metal sheet 30 for assisting in heat radiation, hence accomplishing a better heat-radiating efficiency. Therefore, the LED chip 20 can stably exploit its high-brightness characteristic and will not burn out. In other words, the problem of heat radiation of a high-brightness LED can be effectively solved.

Moreover, in the present invention, the cathode of the LED chip 20 is electrically connected to the cathode circuit 11 at the upper side of the circuit board 10, and the anode of the LED chip 20 is electrically connected with the metal sheet 30 below the circuit board 10. That is, the cathode and anode circuits are located on different faces of the circuit board 10. The metal sheet 30 located at the bottom can be used as an anode contact, while the housing located outside can be used as a cathode contact. Therefore, the connection wires 32 and 56 need not pass through the circuit board 10, hence providing convenient assembly and simplifying the fabrication process.

Although the present invention has been described with reference to the preferred embodiment thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

I claim:

1. A light emitting diode module structure comprising:
a circuit board having a groove;
a metal sheet disposed below said circuit board;
a light emitting diode chip received in said groove, a lower side of said light emitting diode chip being electrically connected to an upper side of said metal sheet, an upper side of said light emitting diode chip being electrically connected to an upper side of said circuit board with a lead, and a gel covering said light emitting diode chip;
a housing having a receiving space therein, said circuit board and said metal sheet being received in said receiving space, said circuit board achieving electric connection with said housing; and
a focusing lens disposed in said receiving space of said housing and located above said light emitting diode chip.

2. The light emitting diode module structure as claimed in claim 1, wherein the upper side of said circuit board has a cathode circuit, and the upper side of said light emitting diode chip is electrically connected to said cathode circuit on the upper side of said circuit board with said lead.

3. The light emitting diode module structure as claimed in claim 1, wherein an area of said metal sheet is smaller than that of said circuit board to allow the outer edge of said metal sheet to shrink more inwards than that of said circuit board.

4. The light emitting diode module structure as claimed in claim 1, wherein an insulator is disposed below said metal sheet, and joins with said housing.

5. The light emitting diode module structure as claimed in claim 1, wherein the lower side of said light emitting diode chip is electrically connected to the upper side of said metal sheet with conducting gel.

6. The light emitting diode module structure as claimed in claim 1, wherein two ends of said receiving space of said housing respectively form a first opening and a second opening, a first stop edge forms at an upper edge of said receiving space, a second stop edge forms at a lower edge of said receiving space, said circuit board and said metal sheet are received in said second opening of said housing, said circuit board abuts said second stop edge for positioning, an upper end of said focusing lens abuts said first stop edge for positioning, a flange is disposed at the upper end of said focusing lens, and said flange abuts against an inner edge of said first opening of said housing.

7. The light emitting diode module structure as claimed in claim 1, wherein a cavity corresponding to said gel and said light emitting diode chip is disposed at a lower end of said focusing lens.
